(19) United States
(12) Patent Application Publication
(10) Pub. No.: US 2024/0413606 A1
(43) Pub. Date: Dec. 12, 2024

(54) CONTROL DEVICE, LIGHT SOURCE DEVICE, TRANSMISSION MODULE, OPTICAL TRANSCEIVER, AND CONTROL METHOD

(71) Applicant: NEC Corporation, Minato-ku, Tokyo (JP)

(72) Inventors: Kenji MIZUTANI, Tokyo (JP); Masaki Oe, Tokyo (JP); Shigeru Mieda, Tokyo (JP)

(73) Assignee: NEC Corporation, Minato-ku, Tokyo (JP)

(21) Appl. No.: 18/699,910

(22) PCT Filed: Nov. 9, 2021
(86) PCT No.: PCT/JP2021/041171

§ 371 Date: Apr. 10, 2024

(51) Int. Cl. H01S 5/06; H01S 5/00; H01S 5/0687

(52) U.S. Cl. CPC H01S 5/0612; H01S 5/0078; H01S 5/0687

(57) ABSTRACT

In order to enable oscillation of transmission light at any oscillation frequency even in an environment in which an environmental temperature varies significantly from an assumed temperature, a control device for a light source including a wavelength variable filter includes a temperature reception means for receiving substrate temperature information being information indicating a substrate temperature being a temperature of a substrate on which the light source is provided, and housing temperature information being information indicating a housing temperature being a temperature of a housing containing the substrate; and a control means for controlling, based on the substrate temperature information and the housing temperature information, the substrate temperature and a refractive index of the wavelength variable filter in such a way that a frequency of transmission light being output by the light source becomes a desired frequency.

### TECHNICAL FIELD

The present invention relates to a control device and the like.

### BACKGROUND ART

In recent years, due to sophistication and diversification of an information communication service, increased capacity is required for an optical communication system. Therefore, a wavelength division multiplexing (WDM) method by which a transmission capacity per fiber can be increased is employed in the optical communication system. Further, in the wavelength division multiplexing (WDM) communication, an optical transceiver equipped with a wavelength variable laser using a plurality of wavelength variable filters that can oscillate at any wavelength of a wavelength band to be used is used. An example of such an optical transceiver is described in PTL 1.

As a related technique, there is a technique described in PTLs 2 to 3.

### CITATION LIST

### Patent Literature

[PTL 1] Japanese Unexamined Patent Application Publication No. 2019-040099
[PTL 2] Japanese Unexamined Patent Application Publication No. 2021-125587
[PTL 3] Japanese Unexamined Patent Application Publication No. 2020-167359

### SUMMARY OF INVENTION

### Technical Problem

As described in PTL 1, a silicone photonics technology can reduce a size of an optical function element represented by a wavelength variable filter by hi-density wiring of light with a high refractive index. The wavelength variable filter using the silicone photonics technology includes a waveguide type filter using an optical resonance effect, such as a ring filter and a grating filter. When this silicone photonics technology is used in an optical transceiver, an optical transceiver using a plurality of wavelength variable filters can be reduced in size. Therefore, application of the optical transceiver using the silicone photonics technology to an optical wavelength variable light source module for communication is under consideration. Usually, the optical wavelength variable light source module is required to operate at a specific frequency standardized by the International Telecommunication Union (ITU), and a frequency deviation needs to be within a few gigahertz. However, in the optical wavelength light source module using the silicone photonics technology, an oscillation frequency tends to change due to an influence of temperature. Therefore, the optical wavelength light source module is placed on a temperature controller inside a sealed package. Further, the oscillation frequency of the optical wavelength light source module is controlled with high accuracy by the temperature controller controlling a temperature of a substrate to be constant.

However, even when the temperature of the substrate is controlled to be constant, a slight but certain extent of unevenness in temperature occurs on the substrate when an environmental temperature changes from an assumed temperature. Note that, the environmental temperature is a temperature of an environment in which the optical wavelength light source module is used. The assumed temperature is a temperature being assumed as the environmental temperature. When a wavelength variable filter based on silicone photonics is used, a temperature change significantly affects a characteristic of an oscillation frequency, even when the temperature change is small. Further, depending on a temperature of a mounting position on the substrate, a characteristic of a transmission wavelength of each wavelength variable filter changes differently. Consequently, transmission light may be oscillated outside of a desired frequency range.

An object of the present invention is to provide a control device and the like that enable oscillation of transmission light at any oscillation frequency, even in an environment in which an environmental temperature varies significantly from an assumed temperature.

### Solution to Problem

In one aspect of the present invention, a control device for a light source including a wavelength variable filter includes: a temperature reception means for receiving substrate temperature information being information indicating a substrate temperature being a temperature of a substrate on which the light source is provided, and housing temperature information being information indicating a housing temperature being a temperature of a housing containing the substrate; and a control means for controlling, based on the substrate temperature information and the housing temperature information, the substrate temperature and a refractive index of the wavelength variable filter in such a way that a frequency of transmission light being output from the light source becomes a desired frequency.

In another aspect of the present invention, a control method for a light source including a wavelength variable filter includes, receiving substrate temperature information being information indicating a substrate temperature being a temperature of a substrate on which the light source is provided, and housing temperature information being information indicating a housing temperature being a temperature of a housing containing the substrate; and controlling, based on the substrate temperature information and the housing temperature information, the substrate temperature and a refractive index of the wavelength variable filter in such a way that a frequency of transmission light being output from the light source becomes a desired frequency.

### Advantageous Effects of Invention

According to the present invention, oscillation of transmission light at any oscillation frequency is enabled even in an environment in which an environmental temperature varies significantly from an assumed temperature.

### BRIEF DESCRIPTION OF DRAWINGS

FIG. 1 is a diagram illustrating a configuration example of a control device according to a first example embodiment of the present invention.

FIG. 2 is a diagram illustrating an example of an operational flow of the control device according to the first example embodiment of the present invention.

FIG. 3 is a diagram illustrating a configuration example of an optical transceiver according to a second example embodiment of the present invention.

FIG. 4 is a diagram illustrating a configuration example of an optical transmission module according to the second example embodiment of the present invention.

FIG. 5 is a diagram illustrating a configuration example of a light source device according to the second example embodiment of the present invention.

FIG. 6 is a diagram illustrating a configuration example of a light source according to the second example embodiment of the present invention.

FIG. 7 is a diagram illustrating a configuration example of a control device according to the second example embodiment of the present invention.

FIG. 8 is a diagram illustrating an example of a phase wavelength characteristic related to control of a substrate temperature.

FIG. 9 is a diagram illustrating a phase wavelength characteristic related to control of a filter temperature.

FIG. 10 is a diagram illustrating a configuration example of an optical transceiver according to a third example embodiment of the present invention.

FIG. 11 is a diagram illustrating a configuration example of an optical transmission module according to the third example embodiment of the present invention.

FIG. 12 is a diagram illustrating a configuration example of a light source device according to the third example embodiment of the present invention.

FIG. 13 is a diagram illustrating a configuration example of a control device according to the third example embodiment of the present invention.

FIG. 14 is a diagram illustrating an example of a transmission characteristic of a wavelength variable filter for frequency detection.

FIG. 15 is a diagram illustrating an example of a transmission characteristic of a wavelength variable filter for frequency detection.

FIG. 16 is a diagram illustrating an example of a transmission characteristic of a wavelength variable filter for frequency detection.

FIG. 17 is a diagram illustrating an example of an operational flow of a control device for a light source according to the third example embodiment of the present invention.

### EXAMPLE EMBODIMENT

### First Example Embodiment

A first example embodiment of the present invention is described. Specific examples of a control device 10 are a control device 20 according to a second example embodiment and a control device 30 according to a third example embodiment, which are described below.

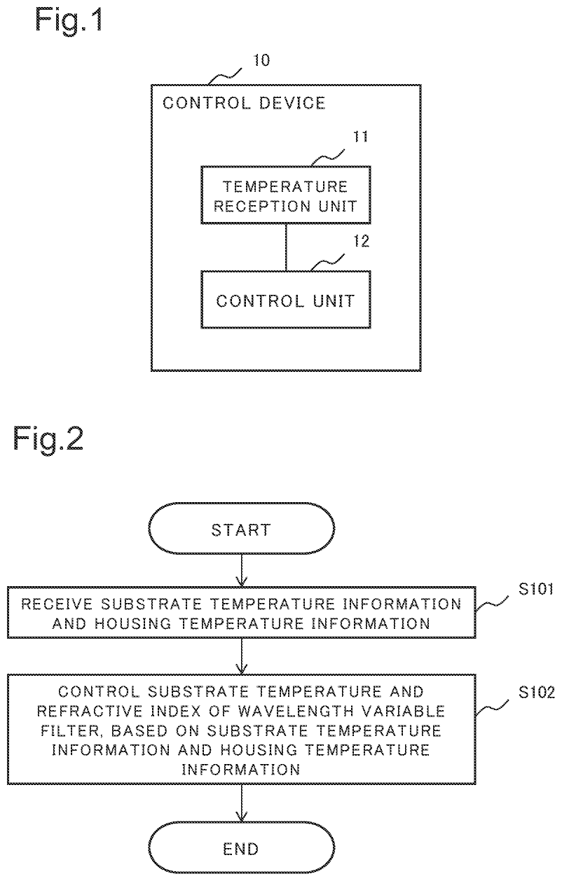

A configuration example of the control device 10 according to the present example embodiment is illustrated in FIG. 1. The control device 10 according to the present example embodiment includes a temperature reception unit 11 (temperature reception means) and a control unit 12 (control means).

The control device 10 is a control device for a light source. The light source includes a wavelength variable filter.

The temperature reception unit 11 receives substrate temperature information being information indicating a substrate temperature and housing temperature information being information indicating a housing temperature. The substrate temperature is a temperature of a substrate on which the light source is provided. The housing temperature is a temperature of a housing containing the substrate. The housing temperature is, for example, a temperature inside the housing or a temperature of an inner surface of the housing. The control unit 12 controls, based on the substrate temperature information and the housing temperature information, the substrate temperature and a refractive index of the wavelength variable filter in such a way that a frequency of transmission light output from the light source becomes a desired frequency.

Next, an example of an operational flow of the control device 10 according to the present example embodiment is described in FIG. 2.

The temperature reception unit 11 receives substrate temperature information and housing temperature information (step S101). The control unit 12 controls, based on the substrate temperature information and the housing temperature information, a substrate temperature and a refractive index of a wavelength variable filter in such a way that a frequency of transmission light output from a light source becomes a desired frequency (step S102).

As described above, in the first example embodiment of the present invention, the control device 10 includes the temperature reception unit 11 and the control unit 12. The temperature reception unit 11 receives substrate temperature information being information indicating a substrate temperature being a temperature of a substrate on which a light source is provided and housing temperature information being information indicating a housing temperature being a temperature of a housing containing the substrate. The control unit 12 controls, based on the substrate temperature information and the housing temperature information, the substrate temperature and a refractive index of a wavelength variable filter, in such a way that a frequency of transmission light output from the light source becomes a desired frequency. Since refractive indices of the wavelength variable filter and a waveguide are changed by controlling the substrate temperature and the refractive index of the wavelength variable filter, the frequency of the transmission light can be adjusted. Thus, oscillation of transmission light at any oscillation frequency is enabled even in an environment in which an environmental temperature varies significantly from an assumed temperature.

### Second Example Embodiment

Next, a second example embodiment of the present invention is described.

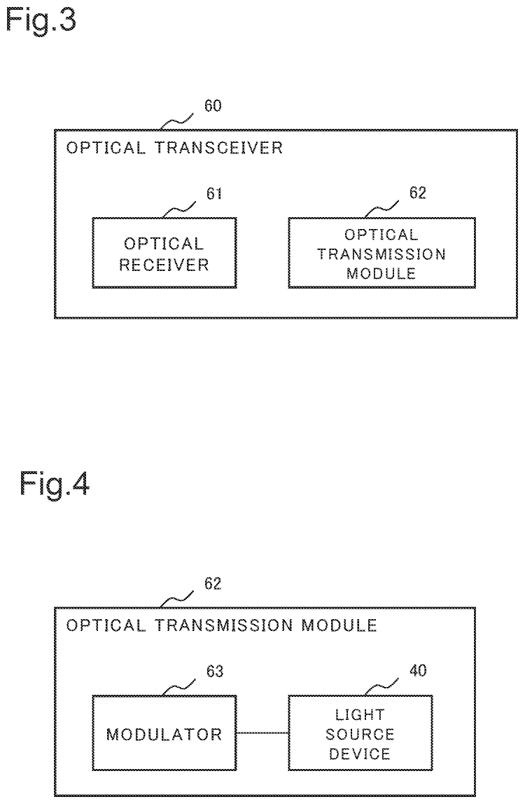

First, a configuration example of an optical transceiver 60 according to the present example embodiment is illustrated in FIG. 3. The optical transceiver 60 includes an optical receiver 61 and an optical transmission module 62. The optical receiver 61 receives an optical signal from outside the optical transceiver 60. The optical transmission module 62 outputs transmission light after being modulated by a modulator 63 described below. The optical receiver 61 and the optical transmission module 62 operate independently.

Next, a configuration example of the optical transmission module 62 according to the present example embodiment is illustrated in FIG. 4. The optical transmission module 62 includes a modulator 63 and a light source device 40. The light source device 40 outputs transmission light. The modulator 63 modulates the transmission light output from the light source device 40 and outputs the modulated transmission light.

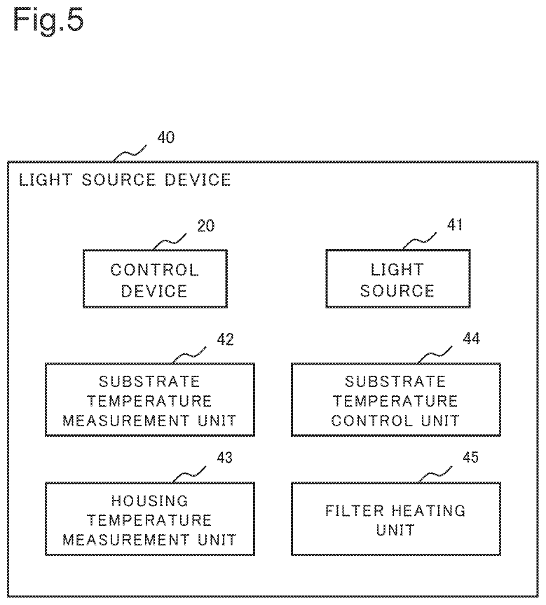

Next, a configuration example of the light source device 40 according to the present example embodiment is illustrated in FIG. 5. The light source device 40 includes a control device 20, a light source 41, a substrate temperature measurement unit 42 (substrate temperature measurement means), a housing temperature measurement unit 43 (housing temperature measurement means), a substrate temperature control unit 44 (substrate temperature control means), and a filter heating unit 45 (filter heating means). The light source 41 outputs transmission light. Functions of the control device 20, the substrate temperature measurement unit 42, the housing temperature measurement unit 43, the substrate temperature control unit 44, and the filter heating unit 45 are described below.

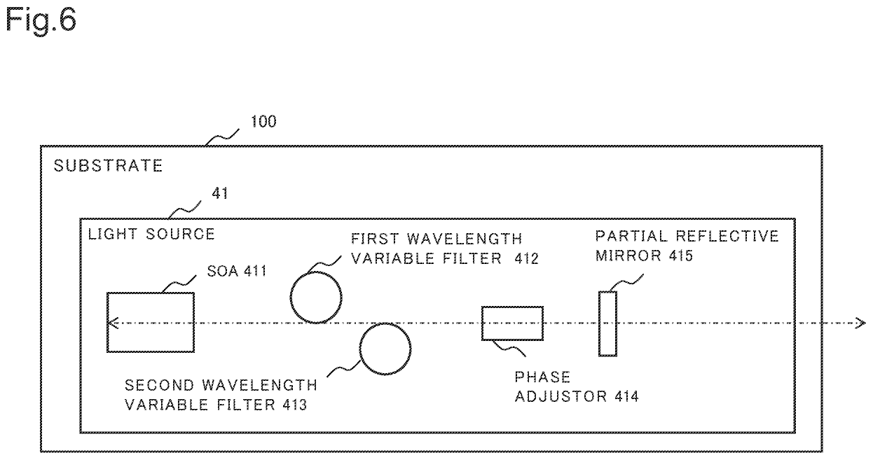

Next, a configuration example of the light source 41 is illustrated in FIG. 6. The light source 41 includes a semiconductor optical amplifier (SOA) 411, a first wavelength variable filter 412, a second wavelength variable filter 413, a phase adjuster 414, and a partial reflective mirror 415. The light source 41 is provided on a substrate 100.

The SOA 411 is a compound semiconductor. An electric current is input to the SOA 411. Further, in the SOA 411, the electric current is converted into light. An external resonator is constituted of an intense reflection surface of the SOA 411 and the partial reflective mirror 415. A plurality of periodic transmission peaks due to the external resonator are external resonator modes. The light generated in the SOA 411 reaches to the partial reflective mirror 415 via the first wavelength variable filter 412, the second wavelength variable filter 413, and the phase adjustor 414. The light reflected by the partial reflective mirror 415 returns to the SOA 411 via the phase adjustor 414, the second wavelength variable filter 413, and the first wavelength variable filter 412, and is reflected by the intense reflection surface of the SOA 411. By repetitive reflection, light of a set frequency is selected by the first wavelength variable filter 412 and the second wavelength variable filter 413 from the plurality of external resonator modes, and the light source 41 oscillates a laser in the selected mode. Note that, an oscillation frequency set herein is, for example, in a range of 191 to 196 THz.

The partial reflective mirror 415 outputs, to the modulator 63, a part of the light as transmission light. The phase adjustor 414 changes an effective cavity length inside the external resonator constituted of the intense reflection surface of the SOA 411 and the partial reflective mirror 415 by changing a refractive index of the waveguide in a section of the phase adjustor 414. Thereby, a mode interval (free spectral range: FSR) of the external resonator is changed, and accordingly, the frequency of the transmission light output from the light source 41 (the partial reflective mirror 415) is also changed.

Note that, refractive indices of the first wavelength variable filter 412 and the second wavelength variable filter 413 change due to a change in temperature, and interval between transmission peak wavelengths due to resonance changes. As a result, a peak wavelength transmitted through the first wavelength variable filter 412 and the second wavelength variable filter 413 also change.

Next, the substrate temperature measurement unit 42, the housing temperature measurement unit 43, the substrate temperature control unit 44, and the filter heating unit 45 of the light source device 40 are descried with reference to FIGS. 5 and 6.

The substrate temperature measurement unit 42 measures a temperature of a substrate. The light source 41 is provided on the substrate. Hereinafter, a temperature of the substrate on which the light source 41 is provided is referred to as a substrate temperature. More specifically, the substrate temperature measurement unit 42 is provided on the substrate. The substrate temperature is a temperature at a position on the substrate where the substrate temperature measurement unit 42 is provided.

The housing temperature measurement unit 43 measures a temperature of a housing containing the substrate. A housing temperature is, for example, a temperature inside the housing or a temperature of an inner surface of the housing. Hereinafter, a temperature of a housing of the optical transceiver 60 is referred to as a housing temperature. More specifically, the housing temperature measurement unit 43 is provided inside the housing. The housing temperature is a temperature at a position inside the housing where the housing temperature measurement unit 43 is provided. Further, since the light source 41 is provided on the substrate, the housing containing the substrate is also a housing of the light source 41. The substrate temperature measurement unit 42 and the housing temperature measurement unit 43 are, for example, thermistors.

The substrate temperature control unit 44 and the filter heating unit 45 are provided on the substrate on which the light source 41 is provided.

The substrate temperature control unit 44 controls the substrate temperature by heating or cooling the substrate. The filter heating unit 45 controls temperatures of the wavelength variable filter included in the light source 41. The filter heating unit 45 may control temperatures of both the first wavelength variable filter 412 and the second wavelength variable filter 413 or may control a temperature of either one of the wavelength variable filters. In the present example embodiment, in order to simplify the control, it is assumed that the filter heating unit 45 controls a temperature of the first wavelength variable filter 412. The substrate temperature control unit 44 and the filter heating unit 45 are, for example, heating elements. Note that, hereinafter, a temperature of a wavelength variable filter is referred to as a filter temperature. In the present example embodiment, a filter temperature is the temperature of the wavelength variable filter 412.

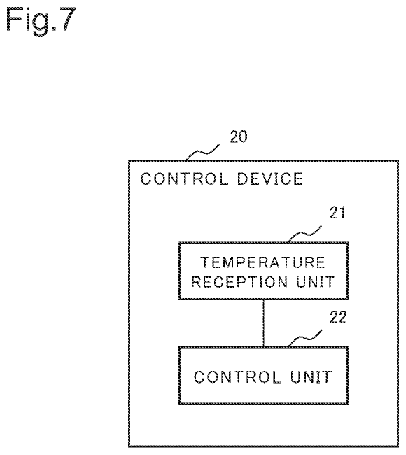

Next, a configuration example of the control device 20 according to the present example embodiment is described with reference to FIG. 7. The control device 20 includes a temperature reception unit 21 and a control unit 22.

The temperature reception unit 21 receives substrate temperature information being information indicating the substrate temperature, from the substrate temperature measurement unit 42. Further, the temperature reception unit 21 receives housing temperature information indicating the housing temperature, from the housing temperature measurement unit 43. For example, the temperature reception unit 21 acquires the substrate temperature information, based on a resistance value of a thermistor in contact with the substrate. The temperature reception unit 21 acquires the housing temperature information, based on a resistance value of a thermistor provided in the housing.

With respect to temperature unevenness on the substrate due to a change in the housing temperature, the control unit 22 controls, based on the substrate temperature information and the housing temperature information, the substrate temperature and refractive index of the wavelength variable filter, in such a way that a frequency of transmission light output from the light source 41 becomes a desired frequency even when the housing temperature changes.

Prior to shipment, the light source 41 is adjusted in such a way as to be able to oscillate at the desired frequency even when refractive indices of the first wavelength variable filter 412 and the second wavelength variable filter 413 and the refractive index of the waveguide in the section of the phase adjustor 414 vary slightly at a reference housing temperature. The control unit 22 controls the substrate temperature in such a way as to be constant.

However, as described above, even when the substrate temperature is controlled to be constant, transmission light may be oscillated outside a desired frequency range when the housing temperature changes due to a change in environmental temperature. When the housing temperature changes from the reference temperature, the control unit 22 according to the present example embodiment controls the substrate temperature and the reflex index of the wavelength variable filter in such a way that the frequency of the transmission light output from the light source 41 becomes the desired frequency. Note that, the control of the substrate temperature and the refractive index of the wavelength variable filter in such a way that the frequency of the transmission light output from the light source 41 becomes the desired frequency may be hereafter referred to as frequency correction.

The control unit 22 according to the present example embodiment controls the substrate temperature by controlling the substrate temperature control unit 44 of the light source device 40. Further, the control unit 22 controls the refractive index of the wavelength variable filter included in the light source 41 by controlling the filter heating unit 45 of the light source device 40. Note that, although the control device 20 according to the present example embodiment controls the refractive index of the wavelength variable filter by controlling the filter heating unit 45, the refractive index of the wavelength variable filter may be controlled by using a method other than temperature control. Further, the control unit 22 controls a refractive index of any one of the two or more wavelength variable filters included in the light source 41. The control unit 22 may control refractive indices of any two or more of the two or more wavelength variable filters included in the light source 41.

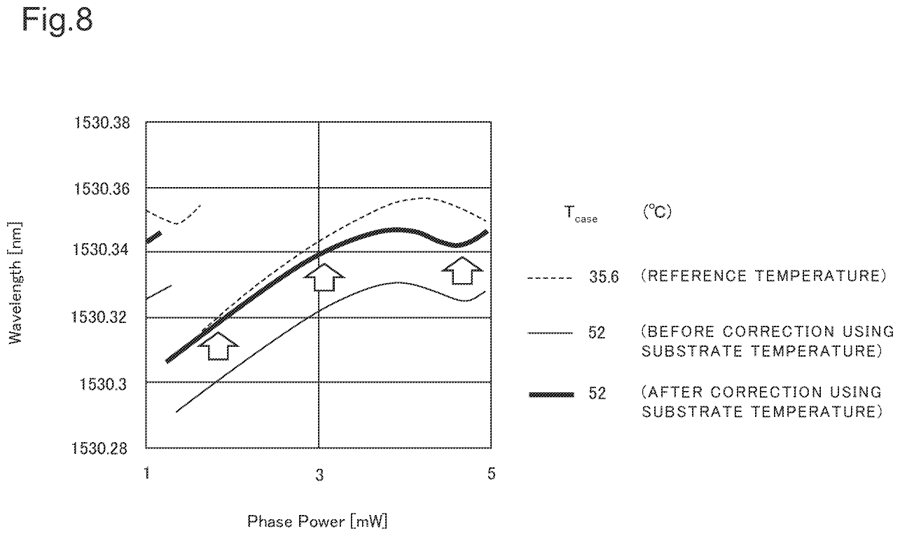

Regarding frequency correction using the substrate temperature, an example of a phase wavelength characteristic in the light source 41 is illustrated in FIG. 8. A horizontal axis of a graph is power (referred to as phase power) given to the phase adjustor 414. A vertical axis of the graph is a wavelength of the transmission light output from the light source 41. The light source 41 can change the wavelength of the transmission light by changing the phase power given to the phase adjustor 414. A relation of the phase power and the wavelength of the transmission light is referred to as a phase wavelength characteristic. “Tcase” refers to the housing temperature.

A dashed line is the phase wavelength characteristic when the housing temperature is 35.6° C. and is a desired phase wavelength characteristic. Further, in this example, a reference temperature (also referred to as an assumed temperature) assumed as a housing temperature at which the desired phase wavelength characteristic is obtained is 35.6° C. A solid line is the phase wavelength characteristic before the control unit 22 executes frequency correction using the substrate temperature. Further, the housing temperature at this occasion is 52° C. Due to a change in the housing temperature, the phase wavelength characteristic is shifted to lower left from the desired phase wavelength characteristic. A bold line is the phase wavelength characteristic after the control unit 22 executes frequency correction using the substrate temperature and before the control unit 22 executes frequency correction using the filter temperature. By the control unit 22 executing the frequency correction using the substrate temperature, the phase wavelength characteristic is brought closer to the desired wavelength characteristic.

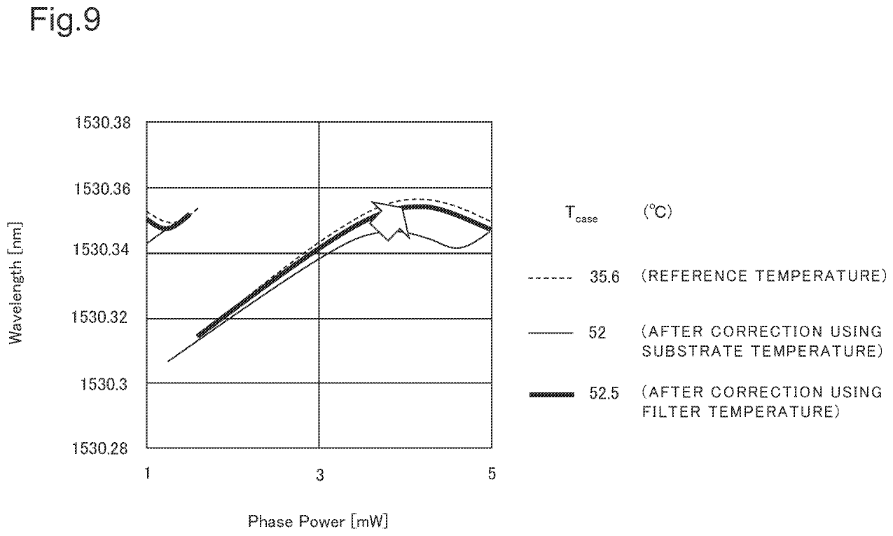

Regarding frequency correction using the filter temperature, an example of the phase wavelength characteristic in the light source 41 is illustrated in FIG. 9. A horizontal axis and a vertical axis of a graph are similar to those in FIG. 8. “Tcase” refers to the housing temperature. A dashed line is the phase wavelength characteristic when the housing temperature is 35.6° C., and is a desired phase wavelength characteristic. A solid line is the phase wavelength characteristic after the control unit 22 executes frequency correction using the substrate temperature and before the control unit 22 executes frequency correction using the filter temperature. A bold line is the phase wavelength characteristic after the control unit 22 executes frequency correction using the filter temperature.

By the control unit 22 controlling the filter temperature, the phase wavelength characteristic is shifted to upper right on the graph, and the phase wavelength characteristic is brought more closer to the desired characteristic. By controlling the filter temperature in addition to the substrate temperature in this way, the phase wavelength characteristic can be brought closer to the desired phase wavelength characteristic. Thereby, the control device 20 can make the frequency of the transmission light output from the light source 41 the desired frequency.

Further, in the present example embodiment, the control device 20 corrects a frequency deviation (a deviation in a vertical direction in the graphs in FIGS. 8 and 9) by using the substrate temperature, and further controls the filter temperature. By correcting the frequency deviation by correcting the substrate temperature, an amount of change in the filter temperature can be minimized. When the frequency deviation is also corrected by using only the filter temperature, influence caused by inner reflection changes, and in some cases, the oscillation frequency becomes unstable. However, in the present example embodiment, since the amount of change in the filter temperature can be reduced, destabilization of the oscillation frequency can be suppressed. Further, temperature control can be simplified by controlling a temperature of only one wavelength variable filter.

The control unit 22 may control, based on relations of power values to the substrate temperature and the housing temperature, the substrate temperature control unit 44 and the filter heating unit 45 in such a way that the frequency of the transmission light becomes the desired frequency. The power values are a power value consumed by the substrate temperature control unit 44 and a power value consumed by the filter heating unit 45.

The light source device 40 may include a storage unit (memory) (not illustrated) storing a lookup table (LUT) storing relations of the power values to the substrate temperature and the housing temperature. Note that, output voltages may be stored in the lookup table (LUT), in association with the substrate temperature and the housing temperature. The output voltages are an output voltage to the substrate temperature control unit 44 and an output voltage to the filter heating unit 45. Herein, the control unit 22 is typically a micro controller (micro controller unit: MCU).

More specifically, an adjuster performs a task described blow, for example, before shipping and the like of the optical transceiver 60, and stores the lookup table in the light source device 40.

For example, the adjuster controls the control device 20 by using a test terminal. In a test mode, the control device 20 controls the substrate temperature control unit 44 and the filter heating unit 45, in accordance with an instruction from the test terminal. Further, in the test mode, the control device 20 outputs the substrate temperature information and the housing temperature information to the test terminal. Further, the adjuster measures a phase wavelength characteristic of transmission light of the optical transceiver 60 by using a measuring instrument.

First, the adjuster changes the housing temperature of the optical transceiver 60 from the reference temperature by changing an environmental temperature. Further, the adjuster controls the substrate temperature control unit 44 via the test terminal in such a way that the phase wavelength characteristic is brought closer to a desired phase wavelength characteristic. The adjuster further controls the filter heating unit 45 via the test terminal in such a way that the phase wavelength characteristic is brought closer to the desired phase wavelength characteristic and that an optical output is maximized. Further, the adjuster stores, as power values (or output voltages) of the substrate temperature control unit 44 and the filter heating unit 45, values at which the phase wavelength characteristic is brought closer to the desired phase wavelength characteristic, in the storage unit of the light source device 40, in association with the substrate temperature and the housing temperature, as the lookup table.

Next, an example of an operational flow of the control device 20 according to the present example embodiment is described with reference to FIG. 2.

The temperature reception unit 21 receives the substrate temperature information from the substrate temperature measurement unit 42. Further, the temperature reception unit 21 receives the housing temperature information from the housing temperature measurement unit 43 (step S101).

The control unit 22 controls, based on the substrate temperature information and the housing temperature information, a substrate temperature and a filter temperature in such a way that a frequency of transmission light output from the light source 41 becomes a desired frequency (step S102). Note that, the control unit 22 may control either one of the substrate temperature and the filter temperature first, or may control the substrate temperature and the filter temperature simultaneously.

As described above, in the second example embodiment of the present invention, the control device 20 includes the temperature reception unit 21 and the control unit 22. The temperature reception unit 21 receives substrate temperature information being information indicating a substrate temperature being a temperature of a substrate on which a light source is provided and housing temperature information being information indicating a housing temperature being a temperature of a housing containing the substrate. The control unit 22 controls, based on the substrate temperature information and the housing temperature information, the substrate temperature and a refractive index of a wavelength variable filter in such a way that a frequency of transmission light output from the light source becomes a desired frequency. Since refractive indices of a waveguide and the wavelength variable filter are changed by controlling the substrate temperature and the refractive index of the wavelength variable filter, the frequency of the transmission light can be adjusted. Thus, oscillation of transmission light at any oscillation frequency is enabled even in an environment in which an environmental temperature varies significantly from an assumed temperature.

Further, the control unit 22 of the control device 20 according to the present example embodiment controls a refractive index of any one of the two or more wavelength variable filters included in the light source 41. Thereby, the control of the refractive index of the wavelength variable filter can be simplified.

The substrate temperature control unit 44 that changes the substrate temperature and the filter heating unit 45 that changes a temperature of the wavelength variable filter are provided on the substrate. The control unit 22 controls the substrate temperature by controlling the substrate temperature control unit 44, and controls the refractive index of the wavelength variable filter by controlling the filter heating unit 45. Thereby control of the substrate temperature and control of the refractive index of the wavelength variable filter can be easily achieved.

Further, the control unit 22 controls, based on relations of the power values consumed by the substrate temperature control unit 44 and the filter heating unit 45 to the substrate temperature and the housing temperature, the substrate temperature and the refractive index of the wavelength variable filter in such a way that the frequency becomes the desired frequency. Thereby, control of the substrate temperature and control of the refractive index of the wavelength variable filter can be easily achieved.

### Third Example Embodiment

Next, a third example embodiment of the present invention is described. In the present example embodiment, a case in which an optical transceiver is further provided with a frequency detection function.

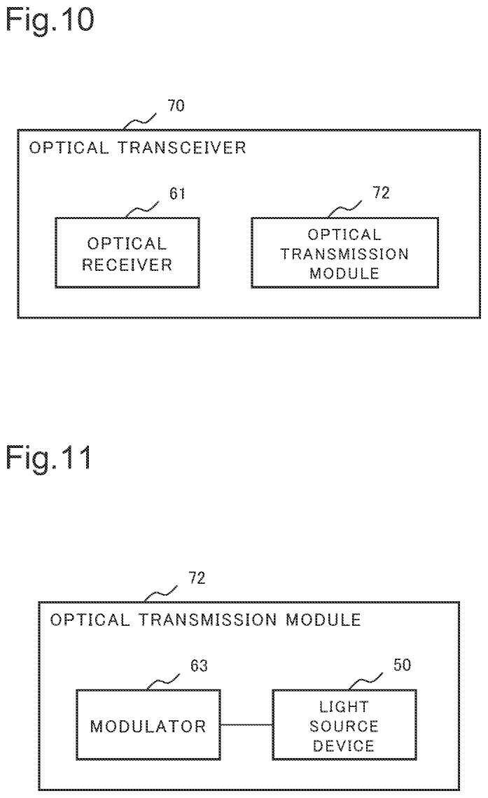

First, a configuration example of an optical transceiver 70 according to the present example embodiment is illustrated in FIG. 10. The optical transceiver 70 includes an optical receiver 61 and an optical transmission module 72. The optical receiver 61 receives light. The optical transmission module 72 outputs modulated transmission light.

Next, a configuration example of the optical transmission module 72 according to the present example embodiment is illustrated in FIG. 11. The optical transmission module 72 includes a modulator 63 and a light source device 50. The light source device 50 transmits transmission light. The modulator 63 modulates the transmission light output from the light source device 50 and outputs the modulated transmission light.

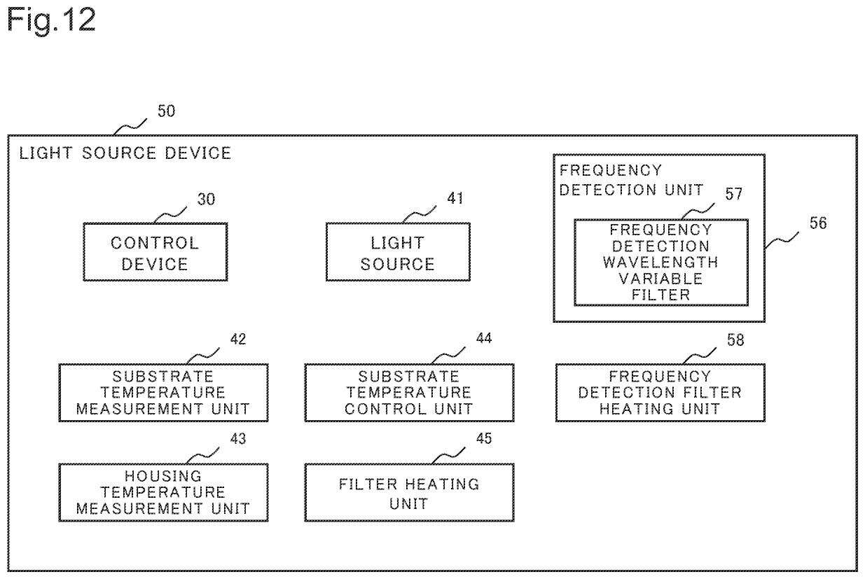

Next, a configuration example of the light source device 50 according to the present example embodiment is illustrated in FIG. 12. The light source device 50 includes a control device 30, a light source 41, a substrate temperature measurement unit 42, a housing temperature measurement unit 43, a substrate temperature control unit 44, and a filter heating unit 45. The light source device 50 further includes a frequency detection unit 56 (frequency detection means) and a frequency detection filter heating unit 58 (frequency detection filter heating means). Since the light source 41, the substrate temperature measurement unit 42, the housing temperature measurement unit 43, the substrate temperature control unit 44, and the filter heating unit 45 are similar to those in the second example embodiment, description thereof is omitted. The control device 30 is described below.

The frequency detection unit 56 detects a frequency of transmission light output from a partial reflective mirror 415. Further, the frequency detection unit 56 outputs information of the detected frequency to the control device 30. In the present example embodiment, the frequency detection unit 56 detects the frequency of the transmission light by using a frequency detection wavelength variable filter 57. The frequency detection wavelength variable filter 57 is provided on a substrate on which the light source 41 is provided.

For example, the frequency detection unit 56 can detect the frequency of the transmission light, based on a ratio of intensity (PD2) of light output from the frequency detection wavelength variable filter 57 to intensity (PD1) of light input to the frequency detection wavelength variable filter 57, and a transmission characteristic of the frequency detection wavelength variable filter 57. Hereinafter, the ratio of PD2 to PD1 is referred to as an input-to-output ration. A transmission characteristic is a characteristic of a relation between the frequency of the transmission light and the input-to-output ratio. Specifically, the frequency detection unit 56 measures PD1 and PD2, and calculates the input-to-output ratio. Further, the frequency detection unit 56 refers to information of the transmission characteristic of the frequency detection wavelength variable filter 57, and detects a frequency related to the input-to-output ratio, as the frequency of the transmission light. In this way, the frequency detection unit 56 can detect the frequency of the transmission light. Note that, the information of the transmission characteristic of the frequency detection wavelength variable filter 57 when a housing temperature is a reference temperature is stored in a storage unit (not illustrated).

The frequency detection filter heating unit 58 controls a temperature of the frequency detection wavelength variable filter 57. The frequency detection filter heating unit 58 is, for example, a heating element. The frequency detection filter heating unit 58 is provided on the substrate on which the light source 41 is provided. Note that, hereinafter, the temperature of the frequency detection filter heating unit 58 is referred to as a frequency detection filter temperature.

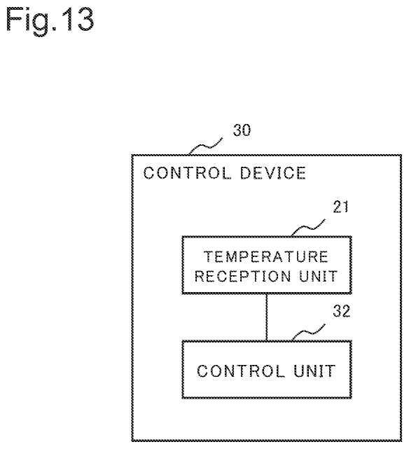

Next, a configuration example of the control device 30 according to the present example embodiment is illustrated in FIG. 13. The control device 30 includes a temperature reception unit 21 and a control unit 32.

The temperature reception unit 21 receives substrate temperature information being information indicating a substrate temperature from the substrate temperature measurement unit 42. Further, the temperature reception unit 21 receives housing temperature information being information indicating the housing temperature from the housing temperature measurement unit 43.

As in the second example embodiment, the control unit 32 controls (performs frequency correction), based on the substrate temperature information and the housing temperature information, a substrate temperature and a refractive index of a wavelength variable filter in such a way that a frequency of transmission light output from the light source 41 becomes a desired frequency.

Further, the control unit 32 outputs information of a frequency detected by the frequency detection unit 56 to an external monitor (not illustrated) and the like.

The control unit 32 further controls, based on the housing temperature, a refractive index of the frequency detection wavelength variable filter 57 in such a way that a frequency detected by the frequency detection unit 56 becomes correct.

Depending on positions of the substrate temperature control unit 44 and the filter heating unit 45 and a shape of a housing, there is temperature unevenness on the substrate. Further, when frequency correction using the substrate temperature is executed by the control unit 32, an amount of temperature change due to the frequency correction is also uneven. Due to this unevenness in the amount of temperature change, a temperature of a first wavelength variable filter 412 and a temperature of the frequency detection wavelength variable filter 57 change by amounts different from each other. Therefore, a difference occurs between the frequency of the transmission light output from the light source 41 and the frequency detected by the frequency detection unit 56. Thus, the control unit 32 according to the present example embodiment controls the refractive index of the frequency detection wavelength variable filter 57 in such a way that a frequency detected in the frequency detection unit 56 becomes correct.

A specific control method of a refractive index of the frequency detection wavelength variable filter 57 is described.

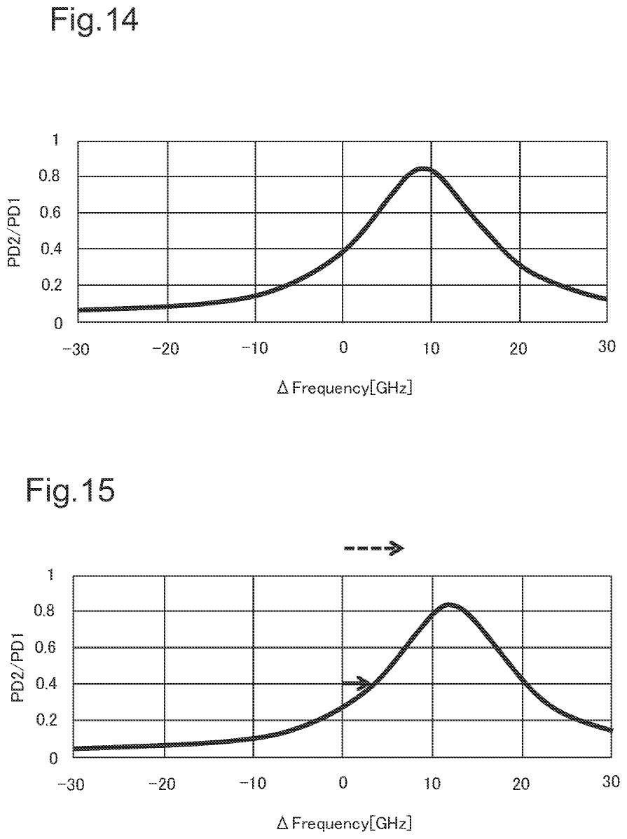

With regard to control of the frequency detection filter temperature, an example of a transmission characteristic of the frequency detection wavelength variable filter 57 is illustrated in FIGS. 14 to 16. A horizontal axis of a graph indicates a difference between a frequency of transmission light and a reference frequency. The reference frequency may be any frequency or the desired frequency. Herein, description is made on an assumption that the reference frequency is any frequency. Further, a vertical axis of the graph indicates a ratio of PD 2 to PD1 (input-to-output ratio).

FIG. 14 illustrates an example of a transmission characteristic of the frequency detection wavelength variable filter 57 when the housing temperature is the reference temperature. The frequency detection unit 56 detects the frequency of the transmission light, based on information of this transmission characteristic.

FIG. 15 illustrates an example of a transmission characteristic of the frequency detection wavelength variable filter 57 when the housing temperature changes from the reference temperature. This is a transmission characteristic before the frequency correction described in the second example embodiment is executed. In FIG. 15, the transmission characteristic is shifted to right as illustrated with a solid-line allow. Further, a dashed-line arrow indicates an amount of shift of a transmission characteristic of the first wavelength variable filter 412. Thus, an amount of shift of transmission characteristic differs between the frequency detection wavelength variable filter 57 and the first wavelength variable filter 412.

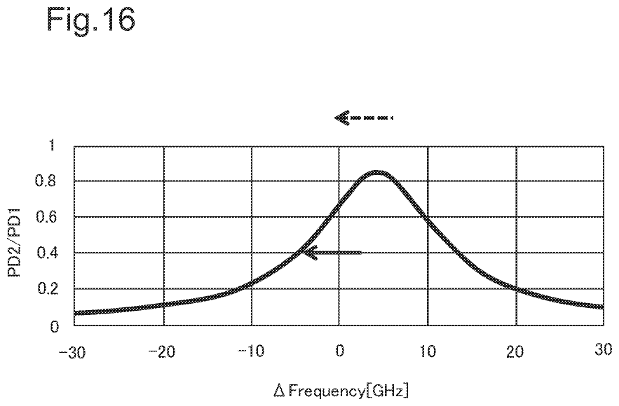

FIG. 16 illustrates an example of a transmission characteristic of the frequency detection wavelength variable filter 57 after the frequency correction is executed. Due to the frequency correction, the transmission characteristic of the first wavelength variable filter 412 returns to a position of the transmission characteristic in a case in which the housing temperature is the reference temperature. However, since the housing temperature is changed by the frequence correction, the transmission characteristic of the frequency detection wavelength variable filter 57 shifts to left from the state illustrated in FIG. 14. In this state, the frequency detection unit 56 cannot correctly detect the frequency of the transmission light. Therefore, the control unit 32 according to the present example embodiment returns the transmission characteristic of the frequency detection wavelength variable filter 57 to the state in FIG. 14 by controlling the refractive index of the frequency detection wavelength variable filter 57.

The control unit 32 controls the refractive index of the frequency detection wavelength variable filter 57, for example, by controlling the frequency detection filter temperature by controlling the frequency detection filter heating unit 58. Note that, the control unit 32 may control the refractive index of the frequency detection wavelength variable filter 57 by using a method other than temperature control.

The light source device 50 may include, for example, a storage unit (not illustrated) storing a lookup table indicating a relation between the housing temperature and a power value consumed by the frequency detection filter heating unit 58. Alternatively, the lookup table may indicate a relation between the housing temperature and an output voltage to the frequency detection filter heating unit 58. The control unit 32 refers to the lookup table and controls the frequency detection filter heating unit 58, based on the housing temperature.

More specifically, an adjuster performs a task described below, for example, before shipping and the like of the optical transceiver 60, and stores the lookup table in the storage unit of the light source device 50.

For example, the adjuster controls the control device 30 by using a test terminal. In a test mode, the control device 30 controls the frequency detection filter heating unit 58 in accordance with an instruction from the test terminal. Further, the control device 30 executes the frequency correction described in the second example embodiment. Due to the frequency correction, the frequency of the transmission light remains unchanged even when the housing temperature changes. Further, in the test mode, the control device 30 outputs the housing temperature information and information indicating the ratio of PD2 to PD1 (input-to-output ratio) to the test terminal.

First, the adjuster changes the housing temperature from the reference temperature by changing an environmental temperature. Further, the adjuster controls the frequency detection filter heating unit 58 via the test terminal, in such a way that the transmission characteristic of the frequency detection wavelength variable filter 57 becomes equal to the transmission characteristic in a case in which the housing temperature is the reference temperature. Further, the adjuster stores, as the lookup table, a power value (or an output voltage) to the frequency detection filter heating unit 58 when the transmission characteristic becomes equal to the transmission characteristic at the reference temperature, in the storage unit of the light source device 50, in association with the housing temperature.

Note that, the method of controlling the refractive index of the frequency detection wavelength variable filter 57 in such a way that a frequency detected by the frequency detection unit 56 becomes correct has been described so far. However, instead of controlling the refractive index of the frequency detection wavelength variable filter 57, the control unit 32 may calculate a correct frequency and may output information of the correct frequency to an external monitor and the like. In the following, a method of calculating a correct frequency is described.

The control unit 32 receives information of a frequency detected by the frequency detection unit 56 from the frequency detection unit 56. Further, the control unit 32 calculates a correct frequency, based on a housing temperature and the frequency detected by the frequency detection unit 56.

Note that, when this method is used, the light source device 50 may not include the frequency detection filter heating unit 58.

The light source device 50 may include, for example, a storage unit (not illustrated) storing a lookup table indicating a relation between the housing temperature and an added value. The added value is a value to be added to the frequency detected by the frequency detection unit 56. The added value may be a negative value. Further, the control unit 32 refers to the lookup table, and calculates a correct frequency by adding the added value associated with the housing temperature to the frequency detected by the frequency detection unit 56.

More specifically, the adjuster performs a task described below, for example, before shipping and the like of the optical transceiver 60, and stores the lookup table in the storage unit of the light source device 50.

For example, the adjuster uses a test terminal. In a test mode, the control device 30 executes the frequency correction described in the second example embodiment. Due to the frequency correction, the frequency of the transmission light remains unchanged even when the housing temperature changes. Further, in the test mode, the control device 30 outputs the housing temperature information and information indicating the frequency (or a frequency) detected by the frequency detection unit 56 to the test terminal.

First, the adjuster changes the housing temperature from the reference temperature by changing the environmental temperature. Further, the adjuster stores, as the lookup table, a value acquired by subtracting the frequency detected by the frequency detection unit 56 from the correct frequency, in the storage unit of the light source device 50, in association with the housing temperature.

Further, when the frequency detected in the frequency detection unit 56 is different from the desired frequency (a set frequency), the control unit 32 may, in addition to the frequency correction described in the second example embodiment, further control the substrate temperature to be raised or lowered in such a way that a detected frequency becomes the desired frequency.

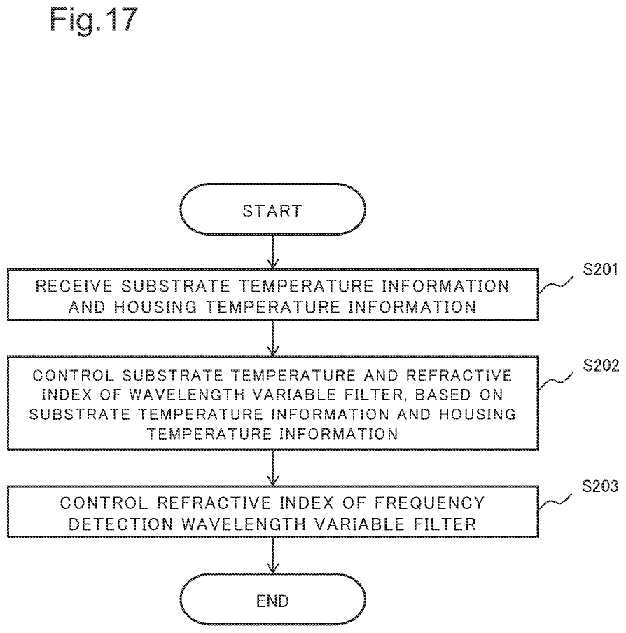

Next, an example of an operational flow of the control device 30 according to the present example embodiment is described with reference to FIG. 17.

The temperature reception unit 21 receives substrate temperature information being information indicating a substrate temperature from the substrate temperature measurement unit 42. Further, the temperature reception unit 21 receives housing temperature information being information indicating a housing temperature from the housing temperature measurement unit 43 (step S201).

The control unit 32 controls, based on the substrate temperature information and the housing temperature information, the substrate temperature and a refractive index of a wavelength variable filter in such a way that a frequency of transmission light output from the light source 41 becomes a desired frequency (step S202).

The control unit 32 further controls, based on the housing temperature information, a refractive index of the frequency detection wavelength variable filter 57 in such a way that a frequency detected by the frequency detection unit 56 becomes correct (step S203). Alternatively, the control unit 32 calculates a correct frequency, based on the housing temperature information.

As described above, in the third example embodiment of the present invention, the control device 30 includes the temperature reception unit 21 and the control unit 32. The temperature reception unit 21 receives substrate temperature information being information indicating a substrate temperature being a temperature of a substrate on which a light source is provided and housing temperature information being information indicating a housing temperature being a temperature of a housing containing the substrate. The control unit 32 controls, based on the substrate temperature information and the housing temperature information, the substrate temperature and a refractive index of a wavelength variable filter in such a way that a frequency of transmission light output from the light source becomes a desired frequency. Since refractive indices of a waveguide and the wavelength variable filter are changed by controlling the substrate temperature and the refractive index of the wavelength variable filter, the frequency of the transmission light can be adjusted. Therefore, oscillation of transmission light at any oscillation frequency is enabled even in an environment in which an environmental temperature varies significantly from an assumed temperature.

In the present example embodiment, the frequency detection wavelength variable filter 57 being a wavelength variable filter for detecting a frequency of transmission light is further provided on the substrate. Further, the control unit 32 controls, based on the housing temperature, a refractive index of the frequency detection wavelength variable filter 57 in such a way that a frequency detected by frequency detection becomes correct. By controlling the refractive index of the frequency detection wavelength variable filter 57, the transmission characteristic of the frequency detection wavelength variable filter 57 can be adjusted to the transmission characteristic (the transmission characteristic used in the frequency detection) in a case in which the housing temperature is a reference temperature. Thus, the frequency detected by the frequency detection can be corrected.

In the present example embodiment, the frequency detection filter heating unit 58 that controls a temperature of the frequency detection wavelength variable filter 57 is further provided on the substrate. Further, the control unit 32 controls the refractive index of the frequency detection wavelength variable filter 57 by controlling the frequency detection filter heating unit 58. Therefore, control of the refractive index of the frequency detection wavelength variable filter 57 can be easily achieved.

Further, the control unit 32 according to the present example embodiment controls the frequency detection filter heating unit 58, based on a relation between the housing temperature and a power value consumed by the frequency detection filter heating unit 58. Therefore, control of the refractive index of the frequency detection wavelength variable filter 57 can be easily achieved.

In the present example embodiment, the frequency detection wavelength variable filter 57 being a wavelength variable filter for detecting a frequency of transmission light is further provided on the substrate. Further, the control unit 32 calculates a correct frequency, based on the housing temperature and the frequency detected by frequency detection, and outputs the correct frequency. Therefore, the correct frequency can be detected as a result of frequency detection.

Further, the control unit 32 according to the present example embodiment calculates a correct frequency, based on a relation between the housing temperature and an added value to the frequency detected by frequency detection. Therefore, calculation of the correct frequency can be easily achieved.

A part or the entirety of the above-described example embodiments may be described as the following supplementary notes, but is not limited thereto.

### (Supplementary Note 1)

A control device for a light source including a wavelength variable filter, the control device comprising:
a temperature reception means for receiving substrate temperature information being information indicating a substrate temperature being a temperature of a substrate on which the light source is provided and housing temperature information being information indicating a housing temperature being a temperature of a housing containing the substrate; and
a control means for controlling, based on the substrate temperature information and the housing temperature information, the substrate temperature and a refractive index of the wavelength variable filter in such a way that a frequency of transmission light being output by the light source becomes a desired frequency.

### (Supplementary Note 2)

The control device according to supplementary note 1, wherein
the control means controls a refractive index of any one of two or more of the wavelength variable filters included in the light source.

### (Supplementary Note 3)

The control device according to supplementary note 1 or 2, wherein
a substrate temperature control means for changing the substrate temperature and a filter heating means for changing a temperature of the wavelength variable filter are provided on the substrate, and
the control means controls the substrate temperature by controlling the substrate temperature control means and controls a refractive index of the wavelength variable filter by controlling the filter heating means.

### (Supplementary Note 4)

The control device according to supplementary note 3, wherein
the control means controls, based on relations of power values consumed by the substrate temperature control means and the filter heating means to the substrate temperature and the housing temperature, the substrate temperature and a refractive index of the wavelength variable filter in such a way that a frequency of the transmission light becomes a desired frequency.

### (Supplementary Note 5)

The control device according to any one of supplementary notes 1 to 4, wherein
a frequency detection wavelength variable filter for frequency detection for the transmission light is further provided on the substrate, and
the control means further controls, based on the housing temperature, a refractive index of the frequency detection wavelength variable filter in such a way that a frequency detected by the frequency detection becomes correct.

### (Supplementary Note 6)

The control device according to supplementary note 5, wherein
a frequency detection filter heating means for controlling a temperature of the frequency detection wavelength variable filter is further provided on the substrate, and
the control means controls a refractive index of the frequency detection wavelength variable filter by controlling the frequency detection filter heating means.

### (Supplementary Note 7)

The control device according to supplementary note 6, wherein
the control means controls the frequency detection filter heating means, based on a relation between the housing temperature and a power value consumed by the frequency detection filter heating means.

### (Supplementary Note 8)

The control device according to any one of supplementary notes 1 to 4, wherein
a frequency detection wavelength variable filter for frequency detection for the transmission light is further provided on the substrate, and
the control means further calculates a correct frequency from the housing temperature and a frequency detected by the frequency detection, and outputs the correct frequency.

### (Supplementary Note 9)

The control device according to supplementary note 8, wherein
the control means calculates a correct frequency from a relation between the housing temperature and an added value to a frequency detected by the frequency detection.

### (Supplementary Note 10)

A light source device comprising:
the control device according to any one of supplementary notes 1 to 9; and
the light source.

### (Supplementary Note 11)

An optical transmission module comprising:
the light source device according to supplementary note 10; and
a modulator that modulates the transmission light.

### (Supplementary Note 12)

An optical transceiver comprising:
the optical transmission module according to supplementary note 11; and
an optical receiver that receives an optical signal.

### (Supplementary Note 13)

A control method for a light source including a wavelength variable filter, the control method comprising:
receiving substrate temperature information being information indicating a substrate temperature being a temperature of a substrate on which the light source is provided, and housing temperature information being information indicating a housing temperature being a temperature of a housing containing the substrate; and
controlling, based on the substrate temperature information and the housing temperature information, the substrate temperature and a refractive index of the wavelength variable filter in such a way that a frequency of transmission light being output by the light source becomes a desired frequency.

### (Supplementary Note 14)

The control method according to supplementary note 13, further comprising
controlling a refractive index of any one of two or more of the wavelength variable filters included in the light source.

### (Supplementary Note 15)

The control method according to supplementary note 13 or 14, wherein
a substrate temperature control means for changing the substrate temperature and a filter heating means for changing a temperature of the wavelength variable filter are provided on the substrate, the control method further comprising
controlling the substrate temperature by controlling the substrate temperature control means, and controlling a refractive index of the wavelength variable filter by controlling the filter heating means.

### (Supplementary Note 16)

The control method according to supplementary note 15, further comprising
controlling, based on relations of power values consumed by the substrate temperature control means and the filter heating means to the substrate temperature and the housing temperature, the substrate temperature and a refractive index of the wavelength variable filter in such a way that a frequency of the transmission light becomes a desired frequency.

### (Supplementary Note 17)

The control method according to any one of supplementary notes 13 to 16, wherein
a frequency detection wavelength variable filter for frequency detection for the transmission light is further provided on the substrate, the control method further comprising
controlling, based on the housing temperature, a refractive index of the frequency detection wavelength variable filter in such a way that a frequency detected by the frequency detection becomes correct.

### (Supplementary Note 18)

The control method according to supplementary note 17, wherein
a frequency detection filter heating means for controlling a temperature of the frequency detection wavelength variable filter is further provided on the substrate, the control method further comprising
controlling a refractive index of the frequency detection wavelength variable filter by controlling the frequency detection filter heating means.

### (Supplementary Note 19)

The control method according to supplementary note 18, further comprising
controlling the frequency detection filter heating means, based on a relation between the housing temperature and a power value consumed by the frequency detection filter heating means.

### (Supplementary Note 20)

The control method according to any one of supplementary notes 13 to 16, wherein
a frequency detection wavelength variable filter for frequency detection for the transmission light is further provided on the substrate, the control method further comprising
calculating a correct frequency from the housing temperature and a frequency detected by the frequency detection and outputting the correct frequency.

### (Supplementary Note 21)

The control method according to supplementary note 20, further comprising calculating a correct frequency from a relation between the housing temperature and an added value to a frequency detected by the frequency detection.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

### REFERENCE SIGNS LIST

10, 20, 30 Control device
11, 21 Temperature reception unit
12, 22, 32 Control unit
40, 50 Light source device
41 Light source
42 Substrate temperature measurement unit
43 Housing temperature measurement unit
44 Substrate temperature control unit
45 Filter heating unit
56 Frequency detection unit
57 Frequency detection wavelength variable filter
60, 70 Optical transceiver

What is claimed is:

1. A control device for a light source including a wavelength variable filter, the control device comprising:
temperature reception circuit configured to receive substrate temperature information being information indicating a substrate temperature being a temperature of a substrate on which the light source is provided, and housing temperature information being information indicating a housing temperature being a temperature of a housing containing the substrate; and
control circuit configured to control, based on the substrate temperature information and the housing temperature information, the substrate temperature and a refractive index of the wavelength variable filter in such a way that a frequency of transmission light being output by the light source becomes a desired frequency.

2. The control device according to claim 1, wherein
the control circuit controls a refractive index of any one of two or more of the wavelength variable filters included in the light source.

3. The control device according to claim 1, wherein
substrate temperature control circuit configured to change the substrate temperature and filter heating circuit configured to change a temperature of the wavelength variable filter are provided on the substrate, and
the control circuit controls the substrate temperature by controlling the substrate temperature control circuit and controls a refractive index of the wavelength variable filter by controlling the filter heating circuit.

4. The control device according to claim 1, wherein
a frequency detection wavelength variable filter for frequency detection for the transmission light is further provided on the substrate, and
the control circuit further controls, based on the housing temperature, a refractive index of the frequency detection wavelength variable filter in such a way that a frequency detected by the frequency detection becomes correct.

5. The control device according to claim 4, wherein
frequency detection filter heating circuit configured to control a temperature of the frequency detection wavelength variable filter is further provided on the substrate, and
the control circuit controls a refractive index of the frequency detection wavelength variable filter by controlling the frequency detection filter heating circuit.

6. The control device according to claim 1, wherein
a frequency detection wavelength variable filter for frequency detection for the transmission light is further provided on the substrate, and
the control circuit further calculates a correct frequency from the housing temperature and a frequency detected by the frequency detection, and outputs the correct frequency.

7. A light source device comprising:
the control device according to claim 1; and
the light source.

8. An optical transmission module comprising:
the light source device according to claim 7; and
a modulator that modulates the transmission light.

9. An optical transceiver comprising:
the optical transmission module according to claim 8; and
an optical receiver that receives an optical signal.

10. A control method for a light source including a wavelength variable filter, the control method comprising:
receiving substrate temperature information being information indicating a substrate temperature being a temperature of a substrate on which the light source is provided, and housing temperature information being information indicating a housing temperature being a temperature of a housing containing the substrate; and
controlling, based on the substrate temperature information and the housing temperature information, the substrate temperature and a refractive index of the wavelength variable filter in such a way that a frequency of transmission light being output by the light source becomes a desired frequency.

11. The control device according to claim 3, wherein
the control circuit controls, based on relations of power values consumed by the substrate temperature control circuit and the filter heating circuit to the substrate temperature and the housing temperature, the substrate temperature and a refractive index of the wavelength variable filter in such a way that a frequency of the transmission light becomes a desired frequency.

12. The control device according to claim 5, wherein
the control circuit controls the frequency detection filter heating circuit, based on a relation between the housing temperature and a power value consumed by the frequency detection filter heating circuit.

13. The control device according to claim 6, wherein
the control circuit calculates a correct frequency from a relation between the housing temperature and an added value to a frequency detected by the frequency detection.

14. The control method according to claim 13, further comprising
controlling a refractive index of any one of two or more of the wavelength variable filters included in the light source.

15. The control method according to claim 13, wherein
a substrate temperature control circuit configured to change the substrate temperature and a filter heating circuit configured to change a temperature of the wavelength variable filter are provided on the substrate, the control method further comprising
controlling the substrate temperature by controlling the substrate temperature control circuit, and controlling a refractive index of the wavelength variable filter by controlling the filter heating circuit.

16. The control method according to claim 15, further comprising
controlling, based on relations of power values consumed by the substrate temperature control circuit and the filter heating circuit to the substrate temperature and the housing temperature, the substrate temperature and a refractive index of the wavelength variable filter in such a way that a frequency of the transmission light becomes a desired frequency.

17. The control method according to claim 13, wherein
a frequency detection wavelength variable filter for frequency detection for the transmission light is further provided on the substrate, the control method further comprising
controlling, based on the housing temperature, a refractive index of the frequency detection wavelength variable filter in such a way that a frequency detected by the frequency detection becomes correct.

18. The control method according to claim 17, wherein
a frequency detection filter heating circuit configured to control a temperature of the frequency detection wavelength variable filter is further provided on the substrate, the control method further comprising
controlling a refractive index of the frequency detection wavelength variable filter by controlling the frequency detection filter heating circuit.

19. The control method according to claim 18, further comprising
controlling the frequency detection filter heating circuit, based on a relation between the housing temperature and a power value consumed by the frequency detection filter heating circuit.

20. The control method according to claim 13, wherein
a frequency detection wavelength variable filter for frequency detection for the transmission light is further provided on the substrate, the control method further comprising
calculating a correct frequency from the housing temperature and a frequency detected by the frequency detection and outputting the correct frequency.
